(19) United States
(12) Patent Application Publication
(10) Pub. No.: US 2023/0118192 A1
(43) Pub. Date: Apr. 20, 2023

(54) PHOTOELECTRIC CONVERSION ELEMENT AND SOLAR CELL MODULE

(71) Applicant: SHARP KABUSHIKI KAISHA, Osaka (JP)

(72) Inventors: Shintaroh MIYANISHI, Osaka (JP); Shinya UEGAKI, Osaka (JP); Tsukasa DEGUCHI, Osaka (JP); Yasunori NAKANISHI, Osaka (JP); Wenchao DAI, Osaka (JP); ATSUSHI FUKUI, Osaka (JP); HIROKAZU ICHINOSE, Osaka (JP); Uran SATO, Osaka (JP); KENJI KIMOTO, Osaka (JP); Takatoshi MAEKAWA, Osaka (JP)

(21) Appl. No.: 17/956,015

(22) Filed: Sep. 29, 2022

(30) Foreign Application Priority Data
Oct. 18, 2021 (JP) 2021-170333

(51) Int. Cl. H01G 9/20; H01L 51/42; H01L 51/00

(52) U.S. Cl. CPC H01G 9/2009; H01L 51/426; H01L 51/4273; H01L 51/0077

(57) ABSTRACT

An photoelectric conversion element in the disclosure is characterized by including: a first conductive layer; a porous hole-blocking layer disposed on the first conductive layer; a porous insulator layer disposed on the porous hole-blocking layer; photoabsorption layers disposed in a pore of the porous hole-blocking layer and in a pore of the porous insulator layer and containing an organic-based photoelectric conversion material; an electron-blocking layer disposed on the porous insulator layer; and a second conductive layer disposed on the electron-blocking layer.

### BACKGROUND OF THE INVENTION

### Field of the Invention

The disclosure relates to a photoelectric conversion element and a solar cell module.

### Description of the Background Art

Photoelectric conversion elements have been employed in, e.g., photosensors, copiers, and solar cell modules. In particular, solar cell modules are fully spreading as representative modalities of use of renewable energy. A solar cell module now spreading is a solar cell module employing an inorganic-based photoelectric conversion element (e.g., a silicon-based solar cell module, a CIGS-based solar cell module, and a CdTe-based solar cell module).

Another solar cell module that has also been investigated is a solar cell module employing an organic-based photoelectric conversion element (e.g., an organic thin-film solar cell module and a dye sensitized solar cell module). Such a solar cell module employing an organic-based photoelectric conversion element can be produced by an application process without use of a vacuum process, thus potentially significantly reducing production cost. Accordingly, solar cell modules employing organic-based photoelectric conversion elements have been expected as next-generation solar cell modules.

An organic-based photoelectric conversion element that has been recently investigated is a photoelectric conversion element that employs, as a photoabsorption layer, a compound having a perovskite-type crystal structure (hereinafter sometimes described as a perovskite compound). Examples of perovskite compounds include a lead complex. Photoelectric conversion elements employing a perovskite compounds as a photoabsorption layer have excellent photoelectric conversion efficiency. Furthermore, investigations have become active for formation of a photoelectric conversion element by making an application fluid of the perovskite compound permeate a mesoporous multi-layer structure, which is promising in view of a multiple scattering effect of light, a production process for cells, and the like.

However, the conventional photoelectric conversion elements formed by making a perovskite compound permeate a mesoporous multi-layer structure tends to have low extraction efficiency of a photoexcitation carrier. The disclosure was made in view of the aforementioned circumstances, and provides a photoelectric conversion element that has improved extraction efficiency of a photoexcitation carrier and excellent photoelectric conversion efficiency.

### SUMMARY OF THE INVENTION

The disclosure provides a photoelectric conversion element including: a first conductive layer; a porous hole-blocking layer disposed on the first conductive layer; a porous insulator layer disposed on the porous hole-blocking layer; photoabsorption layers disposed in a pore of the porous hole-blocking layer and in a pore of the porous insulator layer and containing an organic-based photoelectric conversion material; an electron-blocking layer disposed on the porous insulator layer; and a second conductive layer disposed on the electron-blocking layer.

The photoelectric conversion element in the disclosure has photoabsorption layers disposed in a pore of the porous hole-blocking layer and in a pore of the porous insulator layer, and thus allows an electron generated by photoexcitation in the photoabsorption layer to efficiently transfer to the porous hole-blocking layer. This provides an excellent photoelectric conversion efficiency.

### BRIEF DESCRIPTION OF THE DRAWINGS

FIG. 1 is a schematic cross-sectional view of a photoelectric conversion element in an embodiment of the disclosure.

FIG. 2 depicts a crystal structure of a perovskite compound (CH₃NH₃PbI₃).

FIG. 3 shows schematic diagrams of a reciprocal lattice structure of a perovskite compound (CH₃NH₃PbI₃) and an electron structure thereof.

FIG. 4 shows a relation of the (111) plane corresponding to the reciprocal lattice space R of the crystal structure of a perovskite compound (CH₃NH₃PbI₃).

FIG. 5 is a schematic cross-sectional view of an intermediate product in a production process of a photoelectric conversion element in an embodiment of the disclosure.

FIG. 6 is a schematic cross-sectional view of an intermediate product in a production process of a photoelectric conversion element in an embodiment of the disclosure.

FIG. 7 is a schematic cross-sectional view of an intermediate product in a production process of a photoelectric conversion element in an embodiment of the disclosure.

FIG. 8 is a schematic cross-sectional view of an intermediate product in a production process of a photoelectric conversion element in an embodiment of the disclosure.

FIG. 9 is an enlarged view of the periphery of the electron-blocking layer in FIG. 8.

FIG. 10 depicts a band structure of a photoelectric conversion element in an embodiment of the disclosure.

FIG. 11 is a schematic cross-sectional view of a photoelectric conversion element in an embodiment of the disclosure.

FIG. 12 is a schematic cross-sectional view of a photoelectric conversion element in an embodiment of the disclosure.

FIG. 13 is an enlarged view of the periphery of the electron-blocking layer in FIG. 11.

FIG. 14 is a schematic cross-sectional view of a solar cell module in an embodiment of the disclosure.

FIG. 15 is a partial cross-sectional view of a solar cell module in an embodiment of the disclosure.

FIG. 16 depicts an equivalent circuit of a solar cell module in an embodiment of the disclosure.

### DESCRIPTION OF THE PREFERRED EMBODIMENTS

The photoelectric conversion element in the disclosure is characterized by including: a first conductive layer; a porous hole-blocking layer disposed on the first conductive layer; a porous insulator layer disposed on the porous hole-blocking layer; photoabsorption layers disposed in a pore of the porous hole-blocking layer and in a pore of the porous insulator layer and containing an organic-based photoelectric conversion material; an electron-blocking layer disposed on the porous insulator layer; and a second conductive layer disposed on the electron-blocking layer.

The organic-based photoelectric conversion material is preferably a compound or organic complex having a perovskite-type crystal structure. The electron-blocking layer preferably includes a coating layer coated on the upper face of the porous insulator layer, and a cover layer disposed on the coating layer, and the photoabsorption layer is preferably further disposed between the coating layer and the cover layer. This provides a wider contact area between the photoabsorption layer and the electron-blocking layer, and allows efficient extraction of a hole generated by photoexcitation in the photoabsorption layer, into the second conductive layer.

The energy level at the upper end of the valence band of a material of the porous hole-blocking layer is preferably 0.5 eV or more lower than the energy level at the upper end of the valence band of an organic-based photoelectric conversion material. This enables an electron generated in an organic-based photoelectric conversion material in the photoabsorption layer to transfer to the first conductive layer via the hole-blocking layer, and allows preventing a hole generated in the organic-based photoelectric conversion material from transferring to the hole-blocking layer. The energy level at the lower end of the conduction band of a material of the electron-blocking layer is preferably 0.5 eV or more higher than the energy level at the lower end of the conduction band of the organic-based photoelectric conversion material. This enables blocking of an electron generated by photoexcitation in the photoabsorption layer to transfer to the electron-blocking layer, and allows extraction of a hole generated by photoexcitation in the photoabsorption layer, into a second conductive layer via an electron-blocking layer.

A material of the porous hole-blocking layer is preferably TiO₂, and TiO₂ particles building up the porous hole-blocking layer preferably have a surface including a stacked structure of TiO₂/TiN/TiO₂. Crystal growth of a perovskite compound, which is a photoelectric conversion material, on this surface can cause formation of an interface of a titanium oxide-perovskite compound with less interfacial defects. This allows generation of a built-in potential so as to provide improved extraction efficiency of electrons and improved barrier efficiency of holes. This results in suppression of recombination of a photoexcitation carrier at an interface between a titanium oxide layer and the photoabsorption layer, and allows implementing a high-efficiency photoelectric conversion element.

A material of the electron-blocking layer is preferably Cu₂O, NiO, or ZnS. Use of such a material enables efficient blocking of transfer of an electron photoexcited in an organic-based photoelectric conversion material in the photoabsorption layer to the electron-blocking layer, and allows implementing a high-efficiency solar cell.

A material of the second conductive layer is preferably a metal having a work function of 5.0 eV or more. This enables generation of a bend of a band structure that makes a hole flow smoother, between the photoabsorption layer and the second conductive layer, and allows efficient extraction of a hole generated by photoexcitation in the photoabsorption layer, into the second conductive layer.

The disclosure also provides a solar cell module including a plurality of the photoelectric conversion elements in the disclosure, a base, and a barrier layer. In the solar cell module in the disclosure, the plurality of the photoelectric conversion element is integrated so as to be series-connected on the base, and the barrier layer is disposed so as to be coated on the upper faces of the plurality of the photoelectric conversion elements, wherein a material of the barrier layer is an inorganic material with varistor characteristics. This allows suppression of reduction in electrical generation efficiency due to a shadow on a module, with low cost.

The disclosure will now be described in more detail with reference to a plurality of embodiments. The configurations shown in the drawings or the description below are illustrative, and the scope of the disclosure is not limited to the drawings or the description below.

### First Embodiment

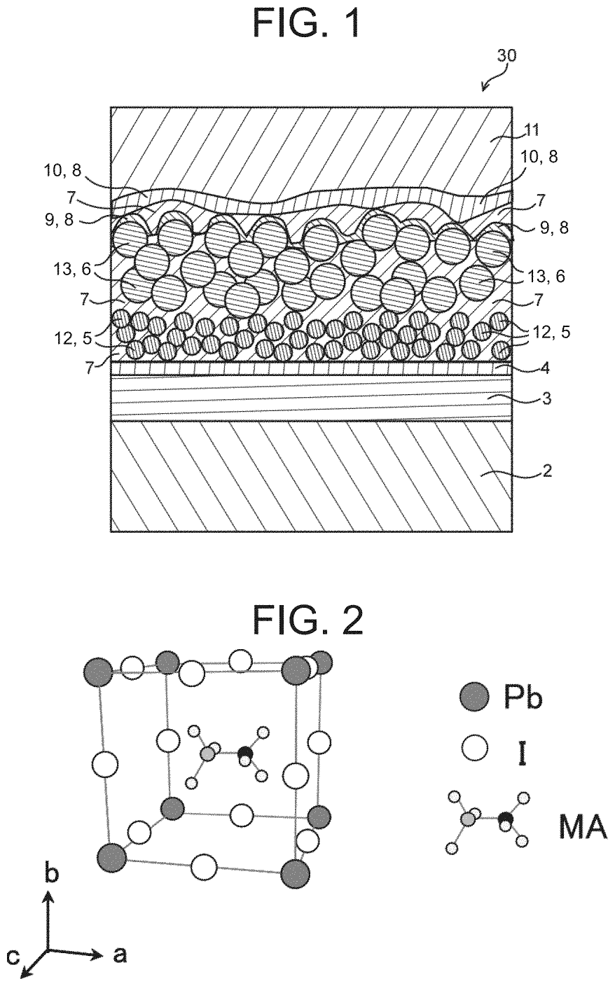

FIG. 1 is a schematic cross-sectional view of a photoelectric conversion element in the embodiment.

A photoelectric conversion element 30 in the embodiment is characterized by including: a first conductive layer 3; a porous hole-blocking layer 5 disposed on the first conductive layer 3; a porous insulator layer 6 disposed on the porous hole-blocking layer 5; photoabsorption layers 7 disposed in a pore of the porous hole-blocking layer 5 and in a pore of the porous insulator layer 6 and containing an organic-based photoelectric conversion material; an electron-blocking layer 8 disposed on the porous insulator layer 6; and a second conductive layer 11 disposed on the electron-blocking layer 8.

At first, description will be made for the principle of a photoelectric conversion element having a perovskite compound, which is a photoelectric conversion material, in a pore of a porous layer.

With regard to perovskite compounds, which have recently drawn attention, it is known that an electron and a hole generated by photoexcitation form no exciton and move as free carriers within a perovskite compound, thereby suppressing recombination due to an exciton bond and extending a lifetime of the carriers.

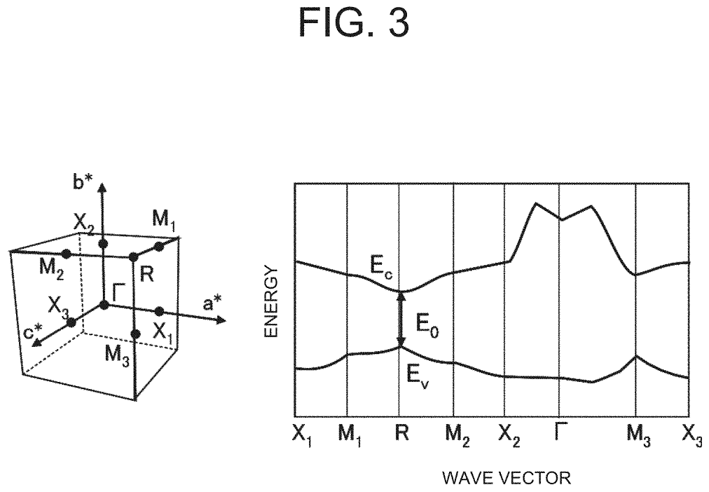

FIG. 2 shows a crystal structure of a perovskite compound (CH₃NH₃PbI₃), and FIG. 3 shows schematic diagrams of a reciprocal lattice structure and an electron structure thereof. In perovskite compounds, the position with the narrowest band gap in a reciprocal lattice space is point R (1,1,1) rather than point Γ (0,0,0), unlike a common direct-transition type electron structure. The conduction electron band Ec at point R mainly consists of a 6p electron orbital of a Pb atom, and the valence band Ev at point R consists of a 6s electron orbital of a Pb atom and a 5p electron orbital of an I atom.

With presence of a band gap in point R and generation of a photoexcitation carrier, the photoexcitation carrier has a momentum at excitation unlike point Γ, and the excited electron and hole have momentum 180° inverted to each other in accordance with the law of conservation of momentum. This is because an electron and a hole form no exciton and move as free carriers within a perovskite compound as with the conventional technologies. Point R (1,1,1) corresponds to eight angles of a rectangular prism for point Γ, absorbs light at each point, and generates an electron in a conduction electron band Ec and a hole in the valence band Ev.

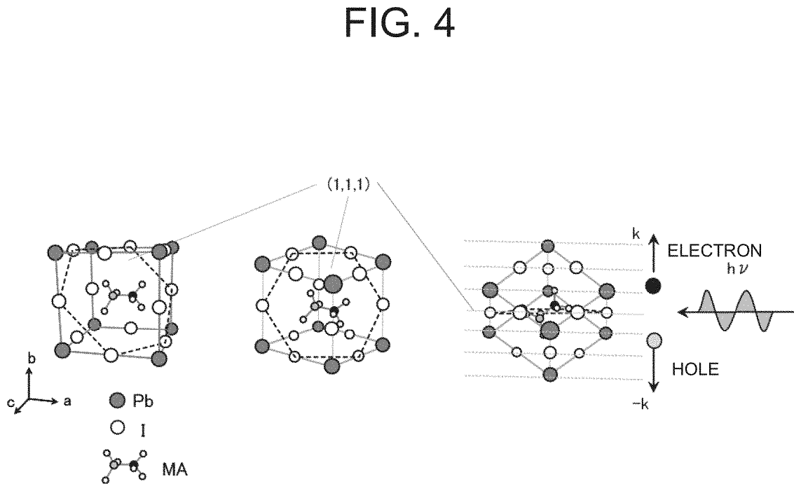

FIG. 4 shows a relation of (1, 1, 1), which is a crystal plane orientation in the real crystal corresponding to the reciprocal lattice space point R of a crystal structure of a perovskite compound (CH₃NH₃PbI₃). FIG. 4 depicts a hexagonal plane consisting of six I atoms (centering a methylammonium ion), and the plane corresponds to (1,1,1), which is a plane orientation in the real crystal corresponding to the reciprocal lattice space point R. When an electric field vector of an incident ray is perpendicular to the plane, optical transition occurs and generates an electron in a 6p electron orbital of a Pb atom that forms a conduction electron band Ec, and a hole in a 6s electron orbital of a Pb atom and a 5p electron orbital of an I atom that form a valence band Ev. The generated photoexcitation carriers are to propagate via electron orbitals forming a conduction electron band Ec and a valence band Ev, with each carrying momentum opposite to the crystal plane orientation (1,1,1) plane.

With such a unique electron structure of perovskite compounds as described above, when light enters a porous stacked structure, light scattering leads to efficient photoabsorption at a reciprocal lattice space point R of a perovskite compound in a pore, and allows each photoexcitation carrier propagating along the crystal plane orientation (1,1,1), to be extracted efficiently via an electron-blocking layer and a hole-blocking layer formed in a porous stacked structure.

Next, description will be made in detail for the photoelectric conversion element 30 in the first embodiment.

The photoelectric conversion element 30 according to the embodiment has a transparent base 2 underlying the first conductive layer 3 (front face electrode), on which a three-layer mesoporous stacked structure is constructed by stacking the porous hole-blocking layer 5, the porous insulator layer 6, and the electron-blocking layer 8 in this order. A pore in the porous layer includes the photoabsorption layer 7 having an organic-based photoelectric conversion material, and the second conductive layer 11 (back face electrode) is disposed on the electron-blocking layer 8. The photoelectric conversion element 30 may be configured such that light enter the photoabsorption layer 7 from the first conductive layer 3 side, such that light enter the photoabsorption layer 7 from the second conductive layer 11 side, or such that light enter the photoabsorption layer 7 from both of the first conductive layer 3 side and the second conductive layer side.

The photoabsorption layer 7 is formed by filling a three-layer mesoporous stacked structure consisting of the porous hole-blocking layer 5/the porous insulator layer 6/the electron-blocking layer 8 with an organic-based photoelectric conversion material solution. This facilitates control of the film thickness of the photoabsorption layer 7, which absorbs light, in production of the photoelectric conversion element 30. This structure also has an effect to suppress a local current leakage between the first conductive layer 3, which is formed on the base 2, and the second conductive layer 11, and the photoelectric conversion element 30 in the embodiment is suitable for a large-area solar cell module.

Furthermore, when light is irradiated on the photoabsorption layer 7, photoexcitation carriers can be efficiently extracted into the first conductive layer 3 and the second conductive layer 11 because of wider contact cross-sectional areas of the photoabsorption layer 7 with the porous hole-blocking layer 5 and the electron-blocking layer 8. The photoelectric conversion element 30 in the embodiment can provide such a separator for photoexcitation carriers, thereby implementing a solar cell attaining high efficiency, low cost, and high rigidity.

Base

Examples of shapes of the base 2 include a flat plate shape, a film shape, and a cylindrical hollow shape. In irradiation of light on the base 2 side face of the photoelectric conversion element 30, the base 2 is transparent. In such case, examples of materials for the base 2 include transparent glass (more particularly, soda lime glass, and non-alkali glass), and transparent resin having thermal resistance. In irradiation of light on the second conductive layer 11 side face of the photoelectric conversion element 30, the base 2 may be opaque. In this case, examples of materials for the base 2 include aluminum, nickel, chromium, magnesium, iron, tin, titanium, gold, silver, copper, tungsten, alloys thereof (e.g., stainless steel), and ceramics.

First Conductive Layer

The first conductive layer 3 (front face electrode) corresponds to a cathode of the photoelectric conversion element 30. Examples of materials forming the first conductive layer 3 include transparent conductive materials (particularly, transparent conductive oxide (TCO)) and non-transparent conductive materials. Examples of the transparent conductive materials include copper iodide (CuI), indium tin oxide (ITO), tin oxide (SnO₂), fluorine-doped tin oxide (FTO), aluminum-doped zinc oxide (AZO), indium zinc oxide (IZO), and gallium-doped zinc oxide (GZO). Examples of non-transparent conductive materials include sodium, sodium-potassium alloy, lithium, magnesium, aluminum, magnesium-silver mixtures, magnesium-indium mixtures, aluminum-lithium alloy, aluminum-aluminum oxide mixture (Al/Al₂O₃), and aluminum-lithium fluoride mixture (AI/LiF). The film thickness of the first conductive layer 3 is not particularly limited, and only has to be a film thickness that can lead to exertion of desired characteristics (e.g., electron transportability and transparency).

Hole-Blocking Layer

The hole-blocking layer is a layer that transports an electron generated by photoexcitation in the photoabsorption layer 7 to the first conductive layer 3, as well as blocks an electron generated by photoexcitation. The hole-blocking layer therefore preferably contains a material (hole-blocking material) that provides easy transfer of an electron generated in an organic-based photoelectric conversion material in the photoabsorption layer 7 to the first conductive layer 3 via the hole-blocking layer, and less transfer of a hole generated in the organic-based photoelectric conversion material to the hole-blocking layer.

The energy level at the upper end of the valence band of the hole-blocking material is preferably 0.5 eV or more lower than the energy level at the upper end of the valence band of the organic-based photoelectric conversion material. In other words, the hole-blocking material is preferably a material that meets the formula: E_{hbv}≤Eₒₚᵥ−0.5 eV. In the formula, E_{hbv} is an energy level at the upper end of the valence band of the hole-blocking material, and Eₒₚᵥ is an energy level at the upper end of the valence band of an organic-based photoelectric conversion material contained in the photoabsorption layer 7. Specific examples of the hole-blocking material include titanium oxide. However, the hole-blocking material to be used can be a material having characteristics that facilitates propagation of an electron and blocking of a hole, such as zinc oxide, alumina, or magnesium oxide, and may also be a mixture of or microparticles formed into core shell shapes from these substances listed above.

In the hole-blocking layer, an electron is required to propagate to the first conductive layer 3 side, and the electric conduction at that time is contemplated to be performed by tunneling conduction. Thus, in order to provide a carrier with a longer halo length (fermi length λf), the hole-blocking layer can be built up with inorganic microparticles having high insulation properties to provide the hole-blocking layer with a doping concentration of 10¹⁶/cm³ or less (λf>90 nm) (hole-blocking material particles 12). The material forming the electron-blocking layer 8 as described later is also required to be an inorganic substance having high insulation properties because of the same reason.

The hole-blocking layer can include the dense hole-blocking layer 4 and the porous hole-blocking layer 5. The dense hole-blocking layer 4 can be omitted. The dense hole-blocking layer 4 is disposed on the first conductive layer 3, and the porous hole-blocking layer 5 is disposed on the dense hole-blocking layer 4. In addition, an electric conductor layer such as a TiN layer may be disposed between the dense hole-blocking layer 4 and the porous hole-blocking layer 5.

The dense hole-blocking layer 4 is a hole-blocking material layer with a relatively small void ratio, and the porous hole-blocking layer 5 is a porous hole-blocking material layer with a higher void ratio than the dense hole-blocking layer 4.

The porous hole-blocking layer 5 can have, e.g., a structure including a plurality of the hole-blocking material particles 12 bound by a binder, or a structure including a plurality of the hole-blocking material particles 12 shaped or sintered. The porous hole-blocking layer 5 can also have a pore between the adjacent hole-blocking material particles 12. The porous hole-blocking layer 5 may also be a mesoporous hole-blocking layer. The porous hole-blocking layer 5 further has the photoabsorption layer 7 disposed in a pore. Accordingly, a composite layer is formed including the porous hole-blocking layer 5 and the photoabsorption layer 7.

Moreover, the porous hole-blocking layer 5 may have a porous structure built up with inorganic microparticles made of a hole-blocking material such as titanium oxide (hole-blocking material particles 12) (particle diameter:10-50 nm) and a binder resin. In this case, addition of the binder resin enables formation of the porous hole-blocking layer 5 on the organic-based film (base 2) at low temperature, and allows formation of a network including the hole-blocking material particles 12 (particle diameter: 10-50 nm) connected by the binder resin in the porous hole-blocking layer 5.

When the hole-blocking material is titanium oxide, the dense hole-blocking layer 4 is a dense titanium oxide layer 4, which has a relatively small void ratio, and the porous hole-blocking layer 5 is a porous titanium oxide layer 5, which is a porous layer with a higher void ratio than the dense titanium oxide layer 4. Description will be made for the dense titanium oxide layer 4 and the porous titanium oxide layer 5, which forms the hole-blocking layer.

Dense Titanium Oxide Layer

Since the dense titanium oxide layer 4 has a low void ratio, an organic-based photoelectric conversion material solution (perovskite compound solution) used for formation of the photoabsorption layer 7 has less permeation into the dense titanium oxide layer 4, in production of the photoelectric conversion element 30. Thus, inclusion of the dense titanium oxide layer 4 in the photoelectric conversion element 30 leads to suppression of contact between the photoabsorption layer 7 and the first conductive layer 3. Inclusion of the dense titanium oxide layer 4 in the photoelectric conversion element 30 also leads to suppression of contact between the first conductive layer 3 and the second conductive layer 11, which causes a reduced electromotive force. The film thickness of the dense titanium oxide layer 4 is preferably 5 nm or more to 200 nm or less, and more preferably 10 nm or more to 100 nm or less. In addition, the filling factor of the dense titanium oxide layer 4 by mass is desirably 90% or more.

The dense titanium oxide layer 4 may have a surface including a stacked structure of titanium oxide/titanium nitride/titanium oxide. Crystal growth of a perovskite compound, which is a photoelectric conversion material, on this surface can cause formation of an interface of a titanium oxide-perovskite compound with less interfacial defects. This allows generation of a built-in potential so as to provide improved extraction efficiency of electrons and improved barrier efficiency of holes. This results in suppression of recombination of a photoexcitation carrier at an interface between a titanium oxide layer and the photoabsorption layer, and allows implementing a high-efficiency photoelectric conversion element. The stacked structure of titanium oxide/titanium nitride/titanium oxide is formed by subjecting the surface of the dense TiO₂ layer 4 to surface modification by nitrogen plasma to form a TiN (NaCl structure) layer having a film thickness of 5-30 nm on the surface of the dense TiO₂ layer 4, and then exposing the TiN layer to the air to form a TiO₂ layer on the surface of the TiN layer.

Porous Titanium Oxide Layer

Since the porous titanium oxide layer 5 has a high void ratio, an organic-based photoelectric conversion material solution (perovskite compound solution) used for formation of the photoabsorption layer 7 easily permeates a pore of the porous titanium oxide layer 5, in production of the photoelectric conversion element 30. Thus the photoabsorption layer 7 is formed in a pore of the porous titanium oxide layer 5, and a composite layer is formed including the photoabsorption layer 7 and the porous titanium oxide layer 5. This enlarges a contact area between the photoabsorption layer 7 and the porous titanium oxide layer 5, allows efficient transfer of an electron generated by photoexcitation in the photoabsorption layer 7 to the porous titanium oxide layer 5, and provide blocking of transfer of a hole generated by photoexcitation to the porous titanium oxide layer 5. The film thickness of the porous titanium oxide layer 5 is preferably 100 nm or more to 500 nm or less, and more preferably 200 nm or more to 300 nm or less. In addition, the filling factor of the porous titanium oxide layer 5 by mass is desirably 30% or more to 70% or less.

A titanium oxide particle (hole-blocking material particle 12) building up the porous titanium oxide layer 5 may have a surface including a stacked structure of titanium oxide/titanium nitride/titanium oxide. Crystal growth of a perovskite compound, which is a photoelectric conversion material, on this surface can cause formation of an interface of a titanium oxide-perovskite compound with less interfacial defects. This allows generation of a built-in potential so as to provide improved extraction efficiency of electrons and improved barrier efficiency of holes. This results in suppression of recombination of a photoexcitation carrier at an interface between the titanium oxide layer 5 and the photoabsorption layer 7, and allows implementing a high-efficiency photoelectric conversion element. The stacked structure of titanium oxide/titanium nitride/titanium oxide is formed by subjecting the surface of the porous titanium oxide layer 5 to surface modification by nitrogen plasma to form a TiN (NaCl structure) layer having a film thickness of 5-30 nm on the surface of a titanium oxide particle, and then exposing the TiN layer to the air to form a TiO₂ layer on the surface of the TiN layer.

Porous Insulator Layer

The porous insulator layer 6 is built up with inorganic microparticles (first insulator particles 13) (particle diameter: 10-100 nm) of an insulator material. The porous insulator layer 6 may have a porous structure built up with the first insulator particles 13 and a binder resin. In this case, addition of the binder resin enables formation of the porous insulator layer 6 on the organic-based film (base 2) at low temperature, and allows formation of a network including the first insulator particles 13 (particle diameter: 10-100 nm) connected by the binder resin in the porous insulator layer 6. Inclusion of the porous insulator layer 6 in the photoelectric conversion element 30 in the embodiment enables prevention of contact between the porous hole-blocking layer 5 and the electron-blocking layer 8, and allows suppression of generation of a short-circuit current.

A material of the first insulator particle 13 built up with the porous insulator layer 6 is desirably a material having a wide band gap such as zirconium oxide, alumina, or silicon oxide. In addition, the first insulator particles 13 may be inorganic microparticles derived by forming each of these materials into a core shell structure. The film thickness of the porous insulator layer 6 is preferably 400 nm or more to 1500 nm or less, and more preferably 500 nm or more to 1000 nm or less. Moreover, the filling factor of the porous insulator layer 6 by mass is desirably 30% or more to 70% or less.

The porous insulator layer 6 can have, e.g., a structure including a plurality of the first insulator particles 13 bound by a binder, or a structure including a plurality of the first insulator particles 13 shaped or sintered. The porous insulator layer 6 can also have a pore between adjacent first insulator particles 13. The porous insulator layer 6 may also be a mesoporous insulator layer. The photoabsorption layer 7 is further disposed in a pore of the porous insulator layer 6. Accordingly, a composite layer is formed including the porous insulator layer 6 and the photoabsorption layer 7.

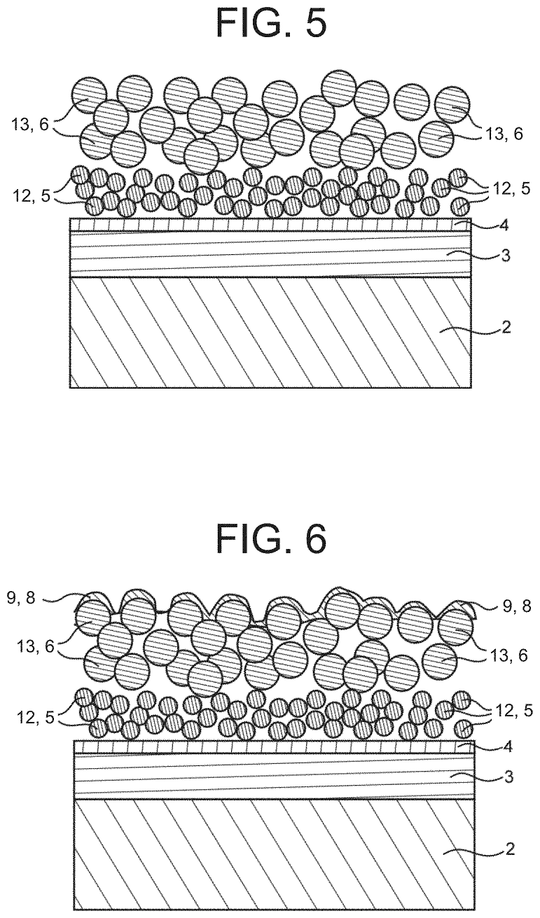

FIG. 5 is a schematic cross-sectional view of an intermediate product derived by forming the first conductive layer 3, the dense titanium oxide layer 4, the porous titanium oxide layer 5, and the porous insulator layer 6 in this order on the base 2. In use of an organic-based film for the base 2, the hole-blocking layer and the porous insulator layer 6 can be formed by depositing the first conductive layer 3 by sputter deposition or the like, applying the dense titanium oxide layer 4, the porous titanium oxide layer 5, and the porous insulator layer 6 by screen printing, and drying at a low temperature of 200 degrees centigrade or less.

Electron-Blocking Layer

The electron-blocking layer 8 is a layer that catches a hole generated in the photoabsorption layer 7 and transfer it to the second conductive layer 11, which is an anode, thereby blocking transfer of an electron generated in the photoabsorption layer 7 to the electron-blocking layer 8. The electron-blocking layer 8 includes a coating layer 9 formed on the porous insulator layer 6, and a cover layer 10. The coating layer 9 is formed before formation of the photoabsorption layer 7 inside a pore of the porous insulator layer 6, and formed so as to be coated on the surface of the first insulator particle 13 on the surface of the porous insulator layer 6. The absorption layer 7 is also formed on the coating layer 9, but is formed so as to expose a portion of the coating layer 9. The cover layer 10 is formed on the coating layer 9 after formation of the photoabsorption layer 7. Accordingly, the photoabsorption layer 7 is present between the coating layer 9 and the cover layer 10. The coating layer 9 and the cover layer 10 also contacts and is integrated with each other partially. Such a millefeuille-shaped layer structure allows efficient extraction of a hole into the second conductive layer 11, by an effect to enhance light reflection at an interface between the electron-blocking layer 8 and the photoabsorption layer 7, and a quantum well structure formed in the electron-blocking layer 8.

A material of the coating layer 9 can be the same material as a material of the cover layer 10. Materials forming the coating layer 9 and the cover layer 10 (materials for the electron-blocking layer 8) can be a material that meets the formula: Eebc≥Eopc+0.5 eV. In the formula, Eebc is an energy level at the lower end of the conduction electron band of a material for the electron-blocking layer 8, and Eopc is an energy level at the lower end of the conduction electron band of an organic-based photoelectric conversion material in the photoabsorption layer 7. In other words, the energy level at the lower end of the conduction band of a material for the electron-blocking layer 8 is 0.5 eV or more higher than the energy level at the lower end of the conduction band of the organic-based photoelectric conversion material in the photoabsorption layer 7. This enables blocking of an electron generated by photoexcitation in the photoabsorption layer 7 to transfer to the electron-blocking layer 8, and allows extraction of a hole generated by photoexcitation in the photoabsorption layer 7, into a second conductive layer 11 via the electron-blocking layer 8.

Specific examples of materials for the electron-blocking layer 8 include inorganic compounds such as Cu₂O, NiO, and ZnS. Use of such a material enables efficient blocking of transfer of an electron photoexcited in an organic-based photoelectric conversion material in the photoabsorption layer 7 to the electron-blocking layer 8, and allows implementing a high-efficiency solar cell.

Each film thickness of the coating layer 9 and the cover layer 10 is desirably 25 nm or more to 80 nm or less. FIG. 6 shows a schematic cross-sectional view of an intermediate after formation of the coating layer 9 for the dense hole-blocking layer 4, the porous hole-blocking layer 5, the porous insulator layer 6, and the electron-blocking layer 8. The coating layer 9 can be formed on the porous insulator layer 6 with sputter deposition. When the coating layer 9 has a film thickness of 25 nm or more to 80 nm or less, a permeation pore(s) can be formed in the coating layer 9. This enables an organic-based photoelectric conversion material solution (perovskite compound solution) used for formation of the photoabsorption layer 7 to pass through the coating layer 9, and allows the organic-based photoelectric conversion material solution to permeate the porous insulator layer 6 and the porous hole-blocking layer 5.

Photoabsorption Layer

The photoabsorption layer 7 is disposed in a pore of the porous hole-blocking layer 5, in a pore of the porous insulator layer 6, and between the coating layer 9 and the cover layer 10. The photoabsorption layer 7 is a layer containing an organic-based photoelectric conversion material. The photoabsorption layer 7 may also be a crystalline layer of an organic-based photoelectric conversion material.

An organic-based photoelectric conversion material contained in the photoabsorption layer 7 is desirably a perovskite compound, and is preferably a compound represented by the general formula: ABX₃ . . . (1) (hereinafter sometimes described as perovskite compound (1)) in view of further improving photoelectric conversion efficiency of the photoelectric conversion element 30. In the general formula (1), A is an organic molecule, B is a metal atom, and X is a halogen atom. In the general formula (1), three Xs may be the same as or different from one another.

Perovskite compound (1) is an organic-inorganic hybrid compound. An organic-inorganic hybrid compound refers to a compound composed of inorganic and organic materials. The photoelectric conversion element 30 using perovskite compound (1), which is an organic-inorganic hybrid compound, is also referred to as an organic-inorganic hybrid photoelectric conversion element.

FIG. 2 is a schematic diagram of a cubic primitive unit lattice of a crystal structure belonging to perovskite compound (1). This primitive unit lattice includes an organic molecule A positioned at the body center of the lattice, metal atoms B positioned at opposite angles of the lattice, and halogen atoms X positioned at respective side centers.

X-ray diffractometry can confirm that an organic-based photoelectric conversion material contained in the photoabsorption layer 7 has a cubic primitive unit lattice. Specifically, a photoabsorption layer containing an organic-based photoelectric conversion material is made on a glass plate, the organic-based photoelectric conversion material is recovered in a powder form, and the recovered, powdered organic-based photoelectric conversion material (photoabsorption material) is measured for a diffraction pattern with a powder X-ray diffraction device. Alternatively, an organic-based photoelectric conversion material is recovered in a powder form from the photoelectric conversion element 30, and the recovered, powdered organic-based photoelectric conversion material (photoabsorption material) is measured for a diffraction pattern with a powder X-ray diffraction device.

In the formula (1), examples of the organic molecule represented by A include alkylamine, alkylammonium, and nitrogen-containing heterocyclic compounds. In perovskite compound (1), an organic molecule represented by A may be only one type of organic molecule, or two or more types of organic molecules.

Examples of the alkylamine include methylamine, ethylamine, propylamine, butylamine, pentylamine, hexylamine, dimethylamine, diethylamine, dipropylamine, dibutylamine, dipentylamine, dihexylamine, trimethylamine, triethylamine, tripropylamine, tributylamine, tripentylamine, trihexylamine, ethylmethylamine, methylpropylamine, butylmethylamine, methylpentylamine, hexylmethylamine, ethylpropylamine, and ethylbutylamine.

The alkylammonium is an ionized substance of alkylamine described above. Examples of the alkylammonium include methylammonium (CH₃NH₃), ethylammonium, propylammonium, butylammonium, pentylammonium, hexylammonium, dimethylammonium, diethylammonium, dipropylammonium, dibutylammonium, dipentylammonium, dihexylammonium, trimethylammonium, triethylammonium, tripropylammonium, tributylammonium, tripentylammonium, trihexylammonium, ethylmethylammonium, methylpropylammonium, butylmethylammonium, methylpentylammonium, hexylmethylammonium, ethylpropylammonium, and ethylbutylammonium.

Examples of the nitrogen-containing heterocyclic compounds include imidazole, azole, pyrrole, aziridine, azirine, azetidine, azete, azole, imidazorine, and carbazole. The nitrogen-containing heterocyclic compound may be an ionized substance. The nitrogen-containing heterocyclic compound that is an ionized substance is preferably phenethylammonium.

The organic molecule represented by A is preferably methylamine, ethylamine, propylamine, butylamine, pentylamine, hexylamine, methylammonium, ethylammonium, propylammonium, butylammonium, pentylammonium, hexylammonium, or phenethylammonium, more preferably methylamine, ethylamine, propylamine, methylammonium, ethylammonium, or propylammonium, and even preferably methylammonium.

In the general formula (1), examples of the metal atom represented by B include lead, tin, zinc, titanium, antimony, bismuth, nickel, iron, cobalt, silver, copper, gallium, germanium, magnesium, calcium, indium, aluminum, manganese, chromium, molybdenum, and europium. In perovskite compound (1), the metal atom represented by B may be only one type of a metal atom, or two or more types of metal atoms. In view of improving photoabsorption properties and charge generation properties of the photoabsorption layer 7 (organic-based photoelectric conversion material), the metal atom represented by B is preferably a lead atom.

In the general formula (1), examples of the halogen atom represented by X include a fluorine atom, a chlorine atom, a bromine atom, and an iodide atom. In perovskite compound (1), the halogen atom represented by X may be one type of halogen atom, or two or more types of halogen atoms. The halogen atom represented by X is preferably an iodide atom in view of narrowing the energy band gap of perovskite compound (1). Specifically, it is preferable that at least one X of three Xs represent an iodide atom, and it is more preferably that three Xs represent iodide atoms.

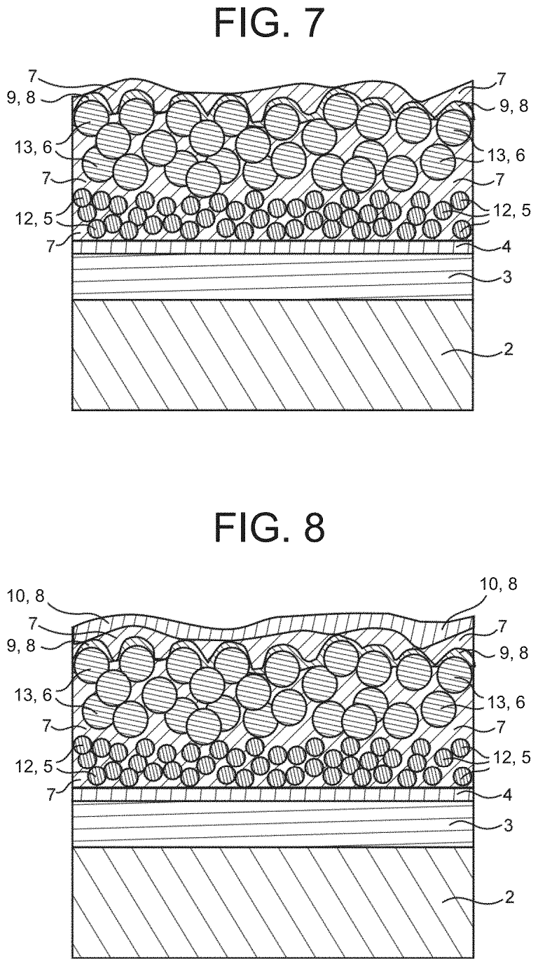

The perovskite compound (1) is preferably a compound represented by the general formula “CH₃NH₃PbX₃ (wherein X represents a halogen atom)”, and more preferably CH₃NH₃PbI₃. Use of a compound represented by the general formula “CH₃NH₃PbX₃” (particularly, CH₃NH₃PbI₃) as perovskite compound (1) allows efficient generation of an electron and a hole in the photoabsorption layer 7, resulting in more improved photoelectric conversion efficiency of the photoelectric conversion element 30. FIG. 7 shows a schematic cross-sectional view of an intermediate product after formation of the photoabsorption layer 7.

A perovskite compound having a perovskite-type crystal structure contained in the photoabsorption layer 7 can be synthesized by using a compound indicated by AX and a compound indicated by BX₂ as raw materials. In particular, the perovskite compound can be synthesized by mixing an AX solution and a BX₂ solution and stirring with heating, thereby providing a perovskite compound solution in which the perovskite compound is dissolved.

When the perovskite compound solution is applied on the coating layer 9, the perovskite compound solution passes through the permeation pore(s) in the coating layer 9 to permeate the porous insulator layer 6, and further permeates the porous hole-blocking layer 5. Since the dense hole-block layer 4 has few pores, the perovskite compound solution penetrates to the bottom of the porous hole-blocking layer 5. At this stage, pores of the porous insulator layer 6 and pores of the porous hole-blocking layer 5 are filled with the perovskite compound solution. On the coating layer 9, an applied film of the perovskite compound solution is also formed so as to expose a portion of the coating layer 9. During permeation of the perovskite compound solution, electrowetting can be used to allow the perovskite compound solution to permeate the porous insulator layer 6 and the porous hole-blocking layer 5 with applying an electric field to the first conductive layer 3 and the perovskite compound solution to control wettability. Subsequently, the intermediate product is heated to dry up the perovskite compound solution, thereby enabling deposition and crystallization of the perovskite compound in the pores of the porous insulator layer 6, in the pores of the porous hole-blocking layer 5, and on the coating layer 9, and allowing formation of the photoabsorption layer 7. Examples of applying methods for the perovskite compound solution include, but not particularly limited to, screen printing, immersion application, inkjet printing, spray application, and slide hopper application.

Inclusion of the photoabsorption layer 7 in pores of the porous hole-blocking layer 5 provides a wider contact area between the porous hole-blocking layer 5 and the photoabsorption layer 7, and allows an electron generated by photoexcitation in the photoabsorption layer 7 to efficiently transfer to the porous hole-blocking layer 5.

Formation of the photoabsorption layer 7 in pores of the porous insulator layer 6 and in pores of the porous hole-blocking layer 5 results in covering of the photoabsorption layer 7 with a porous substance, thus providing improved water vapor barrier properties and rigidity of the photoelectric conversion element 30. Therefore, even when the base 2 is a flexible film, the photoelectric conversion element 30 can have high reliability.

Formation of the photoabsorption layer 7 in pores of the porous insulator layer 6 and in pores of the porous hole-blocking layer 5 also facilitates control of the film thickness of a photoelectric conversion layer (hole-block layer+photoabsorption layer+electron-blocking layer).

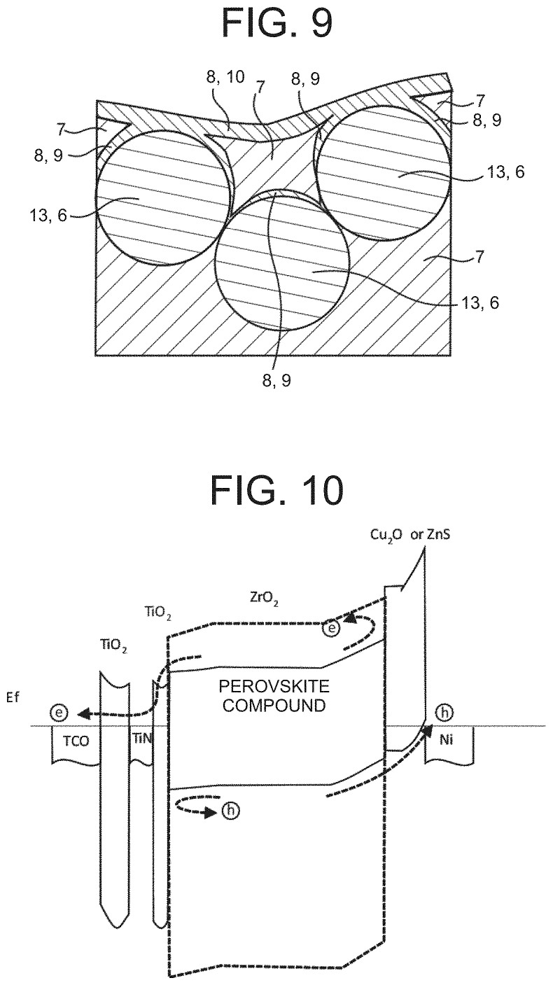

After formation of the photoabsorption layer 7, the cover layer 10 (electron-blocking layer 8) is formed on the photoabsorption layer 7. FIG. 8 is a schematic cross-sectional view of an intermediate product after formation of the cover layer 10. FIG. 9 shows an enlarged view of the periphery of the electron-blocking layer 8 in FIG. 8. A structure is formed including an interposed portion of the photoabsorption layer 7, which faces the coating layer 9 and the cover layer 10, and the electron-blocking layer 8 itself represents a porous structure. Wettability of an organic-based photoelectric conversion material solution and the coating layer 9 causes the coating layer 9 to be partially exposed, thus leading to presence of a site connecting the exposed portion to the cover layer 10. This allows a hole generated in the photoabsorption layer 7 to be extracted via the coating layer 9 and the cover layer 10 into the second conductive layer 11. Moreover, formation of the photoabsorption layer 7 between the coating layer 9 and the cover layer 10 provides a wider contact area between the photoabsorption layer 7 and the electron-blocking layer 8, and allows efficient extraction of a hole generated by photoexcitation in the photoabsorption layer 7, into the second conductive layer 11.

Examples of organic solvents for the perovskite compound solution include aromatic hydrocarbons such as toluene, xylene, mesitylene, tetralin, diphenylmethane, dimethoxybenzene, and dichlorobenzene; halogenated hydrocarbons such as dichloromethane, dichloroethane, and tetrachloropropane; ethers such as tetrahydrofuran (THF), dioxane, dibenzyl ether, dimethoxymethyl ether, and 1,2-dimethoxyethane; ketones such as methyl ethyl ketone, cyclohexanone, acetophenone, and isophorone; esters such as methyl benzoate, ethyl acetate, and butyl acetate; sulfur-containing solvents such as diphenyl sulfide; fluorine-based solvents such as hexafluoroisopropanol; aprotic polar solvents such as N,N-dimethylformamide, N,N-dimethylacetamide, and dimethyl sulfoxide; alcohols such as methanol, ethanol, and isopropanol; and glyme-based solvents such as ethylene glycol and diethylene glycol monomethyl ether. These solvents can be employed alone or as a mixed solvent. Water may be mixed in these solvents. Among these solvents, in view of concern for the global environment, a non-halogen-based organic solvent is preferably used. In addition to this, the perovskite compound solution may further contain an additive such as an antioxidant, a viscoelasticity modifier, an antiseptic, or a curing catalysts.

Protective Film

The photoelectric conversion element 30 may have a protective film between the photoabsorption layer 7 on the coating layer 9 and the cover layer 10. A material of the protective film can be an organic resin. Presence of the protective film allows protection of the surface of a crystallized organic-based photoelectric conversion material from plasma damage, when the cover layer 10 is formed by sputter deposition.

A material of the protective film to be used is an organic resin described below.

Examples of the organic resin include vinyl resins such as polymethyl methacrylate, polystyrene, and polyvinyl chloride; thermoplastic resins such as polycarbonate, polyester, polyester carbonate, polysulfone, polyarylate, polyamide, methacrylic resins, acrylic resins, polyether, polyacrylamide, and polyphenylene oxide; thermosetting resins such as epoxy resins, silicone resins, polyurethane, phenol resins, alkyd resins, melamine resins, phenoxy resins, polyvinyl butyral, and polyvinyl formal; partially crosslinked products of these resins; and copolymer resins containing two or more of the constitutional units contained in these resins (insulating resins such as vinyl chloride-vinyl acetate copolymer resins, vinyl chloride-vinyl acetate-maleic anhydride copolymer resins, and acrylonitrile-styrene copolymer resins). These film-forming resins can be used alone or in combination with two or more types, but any other resin can also be used as long as meeting the requirement.

The protective film may contain a hole transporter material in addition to an organic resin. Examples of the hole transporter materials include organic hole transporter materials and inorganic hole transporter materials.

Examples of the organic hole transporter materials include Spiro-MeOTAD (2, 2′, 7, 7′-tetrakis[N, N-di-P-methoxyphenylamino]-9, 9′-spirobifluorene), pyrazoline compounds, arylamine compounds, stilbene compounds, enamine compounds, polypyrrole compounds, polyvinylcarbazole compounds, polysilane compounds, butadiene compounds, polysiloxane compounds having aromatic amine in a side chain or a main chain, polyaniline compounds, polyphenylene vinylene compounds, polythienylene vinylene compounds, and polythiophene compounds. The organic hole transporter material is particularly preferably a butadiene compound, a bis-butadiene compound, and a conductive polymer such as PEDOT/PSS.

Examples of the inorganic hole transporter material include carbon nanotube and copper thiocyanate (CuSCN). Examples of the carbon nanotube include a multi-layer carbon nanotube (MWCNT) and a single-layer carbon nanotube (SWCNT). The hole transporter material is preferably a carbon nanotube, and more preferably a multi-layer carbon nanotube.

Second Conductive Layer

The second conductive layer 11 corresponds to an anode of the photoelectric conversion element 30. Examples of the material forming the second conductive layer 11 include metal, transparent conductive inorganic materials, conductive microparticles, and conductive polymers (particularly, transparent conductive polymers). Examples of the metal include nickel, gold, silver, and platinum. Examples of the transparent conductive inorganic materials include copper iodide (CuI), indium tin oxide (ITO), tin oxide (SnO₂), fluorine-doped tin oxide (FTO), aluminum-doped zinc oxide (AZO), indium zinc oxide (IZO), and gallium-doped zinc oxide (GZO). Examples of the conductive microparticles include a silver nanowire and a carbon nanofiber. Examples of the transparent conductive polymers include a polymer containing poly(3,4-ethylenedioxythiophene) and polystyrene sulfonic acid (PEDOT/PSS).

In order to efficiently generate a built-in potential in a three-layer mesoporous stacked structure (porous hole-blocking layer+porous insulator layer+electron-blocking layer) filled with an organic-based photoelectric conversion material, metal having a work function Φ≥5.0 eV is preferably used as a material for the second conductive layer 11. This provides a structure that extracts an electron from the first conductive layer 3 formed on the base 2 side, and a hole from the second conductive layer 11 side, and allows attaining a smooth flow of the hole at an interface between the electron-blocking layer 8 and the second conductive layer 11 in a hole extraction part, thereby implementing a high efficiency solar cell. A material of the second conductive layer 11 is e.g., metal nickel.

FIG. 10 depicts a band structure of an element indicating flows of carriers during photoexcitation in the photoelectric conversion element 30. In the band diagram in FIG. 10, a material of the first conductive layer 3 is TCO (transparent conductive oxide); a material of the hole-blocking layer is titanium oxide having a surface including a stacked structure of TiO₂/TiN/TiO₂; a material of the porous insulator layer 6 is ZrO₂; a material of the photoabsorption layer 7 is a perovskite compound (CH₃NH₃PbI₃); a material of the electron-blocking layer 8 is Cu₂O or ZnS; and a material of the second conductive layer 11 is metal nickel.

Table 1 shows crystalline lattice constants of TiO₂, TiN, CH₃NH₃PbI₃, ZrO₂, and ZrN. In addition, Table 2 shows work functions, band gaps (Eg), energy levels at the lower ends of the conduction bands (Ec, LUMO), energy levels at the upper ends of the valence bands (Ev, HOMO) of TCO, TiO₂, TiN, CH₃NH₃PbI₃, ZrO₂, Cu₂O, ZnS, and Ni.

Note that the description for a photoelectric conversion element included in the solar cell module in the third embodiment also applies to the photoelectric conversion element in the first embodiment unless there is a contradiction.

TABLE 1

| | | | Perovskite | | |
|---|---|---|---|---|---|
| | | | compound | | |
| | TiO₂ | TiN | CH₃NH₃ PbI₃ | | |
| | (Rutile structure) | (NaCl structure) | (tetragon) | ZrO₂ | ZrN |
| Lattice | a = 0.459 nm | a = 0.423-0.425 nm | a = 0.88 nm | a = 0.515 nm | a = 0.457 nm |
| constant | e = 0.296 nm | | e = 1.27 nm | | |

TABLE 2

| | | | | Perovskite | | | | |
|---|---|---|---|---|---|---|---|---|
| | | | | cornpound | | | | |
| | TCO | TiO₂ | TiN | CH₃NH₃PbI₃ | ZrO₂ | Cu₂O | ZnS | Ni |
| Work | −4.7 | −4.5 | −4.6 | −4.65 | −5.94 | −5.0 | −5.5 | −5.5 |
| function | | | | | | | | |
| (eV) | | | | | | | | |
| Eg (eV) | — | 3 | — | 1.5 | 5.0 | 2.1 | 3.6 | — |
| Ec. | — | −4.0 | — | −3.9 | −3.4 | −3.2 | −1.7 | — |
| LUMO | | | | | | | | |
| (eV) | | | | | | | | |
| Ev. | — | −7.0 | — | −5.4 | −8.4 | −5.3 | −5.3 | — |
| HOMO | | | | | | | | |
| (eV) | | | | | | | | |

### Second Embodiment

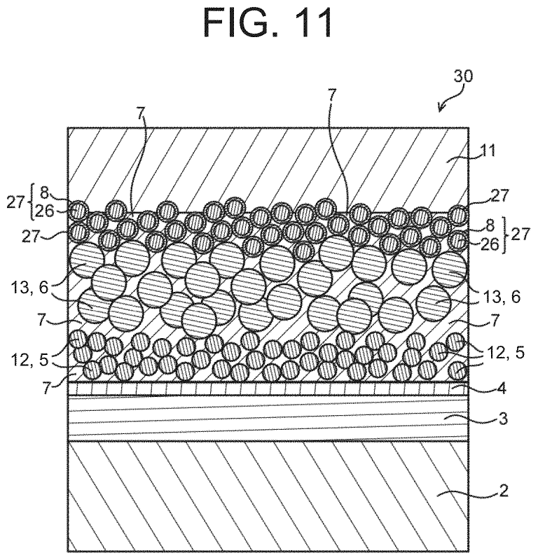

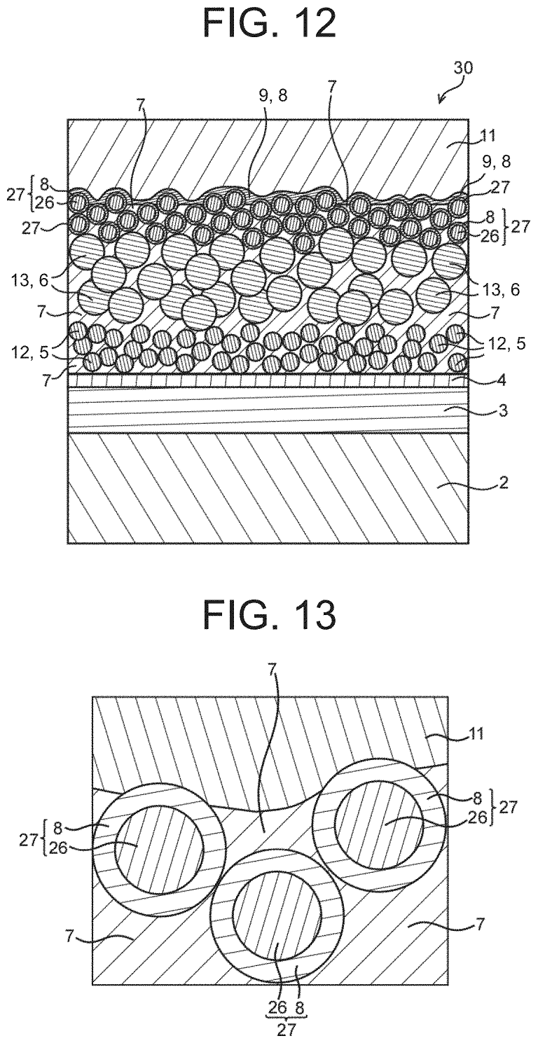

FIG. 11 and FIG. 12 are schematic cross-sectional views of a photoelectric conversion element in the second embodiment. FIG. 13 is an enlarged view of the periphery of the electron-blocking layer in FIG. 11.

The electron-blocking layer 8 in photoelectric conversion element 30 in the second embodiment is included in a porous layer formed by assembling a plurality of electron-blocking material particles 27 each having a core shell structure. The electron-blocking material particle 27 includes a second insulator particle 26, which is made of a material having a wide band gap such as zirconium oxide, alumina, or silicon oxide and has a particle diameter of 10-50 nm; and an electron-blocking layer 8, which covers the surface of the second insulator particle 26. A material of the electron-blocking layer 8 is an inorganic compound such as Cu₂O, NiO, and ZnS, and the thickness of the electron-blocking layer 8 is 10-50 nm. As with the electron-blocking layer 8 having a millefeuille-shaped layer structure in the first embodiment, the second embodiment also enables efficient extraction of a hole into the second conductive layer 11 by forming a quantum well structure that allows a hole to conduct into the electron-blocking layer 8. Moreover, a reflection effect of light in the electron-blocking layer 8 causes suppression of photoabsorption on the second conductive layer 11 side, and provides improved efficiency.

As can be seen in the photoelectric conversion element 30 shown in FIG. 12, the coating layer 9 (electron-blocking layer 8) may be formed between a porous layer of the electron-blocking material particles 27 and the second conductive layer 11 as with the first embodiment. Formation of the coating layer 9 causes partial formation of a millefeuille-shaped layer structure, and attains enhancement of extraction efficiency of a hole and a reflection effect of light.

In the photoelectric conversion element 30 in the third embodiment, the photoabsorption layer 7 is also disposed in a pore of a porous layer of the electron-blocking material microparticle 27.

Such configuration enables efficient blocking of transfer of an electron photoexcited in an organic-based photoelectric conversion material in the photoabsorption layer 7 to the electron-blocking layer 8, and efficient extraction of a hole into the second conductive layer 11, thereby allowing implementing a high-efficiency solar cell.

Table 3 is a table indicating whether a quantum well is formed in the electron-blocking layer.

Other configurations are the same as those in the first embodiment. The description on the first embodiment applies to the second embodiment unless any contradictions occur.

TABLE 3

| | Single | Millefeuille- | Core |
|---|---|---|---|
| | particle | shaped layer | shell |
| | structure | structure | structure |
| Formation of | No | Yes | Yes |
| quantum well | | | |
| structure | | | |

### Third Embodiment

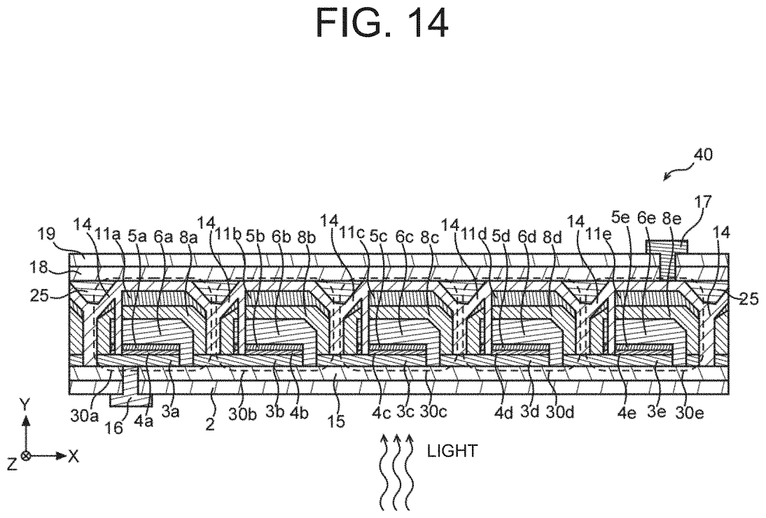

The third embodiment relates to a solar cell module. FIG. 14 is a schematic cross-sectional view of a solar cell module in the embodiment.

A solar cell module 40 in the embodiment includes a plurality of photoelectric conversion elements 30a-30e and the base 2, and the plurality of photoelectric conversion elements 30a-30e is integrated so as to be series-connected on the base 2. Each of the photoelectric conversion elements 30a-30e corresponds to the photoelectric conversion element 30 in the first embodiment.

The photoelectric conversion elements 30a-30e includes: first conductive layers 3a-3e, dense hole-blocking layers 4a-4e and porous hole-blocking layers 5a-5e disposed on the first conductive layers 3a-3e; porous insulator layers 6a-6e disposed on the porous hole-blocking layers 5a-5e; photoabsorption layers disposed in pores of the porous hole-blocking layers 5a-5e and in pores of the porous insulator layers 6a-6e and containing an organic-based photoelectric conversion material; electron-blocking layers 8a-8e disposed on the porous insulator layers 6a-6e; and second conductive layers 11a-11e disposed on the electron-blocking layers 8a-8e. The photoabsorption layers are disposed in pores, and thus omitted in FIG. 14.

Photoelectric conversion layers of the photoelectric conversion elements 30a-30e include the dense hole-blocking layers 4a-4e, the porous hole-blocking layers 5a-5e (including the photoabsorption layers in pores), the porous insulator layers 6a-6e (including the photoabsorption layers in pores), and the electron-blocking layers 8a-8e, and a first barrier layer 14 is disposed so as to cover the side faces of the photoelectric conversion layers. The first barrier layer 14 is a dense inorganic material layer.

In the solar cell module 40 in the embodiment, the plurality of photoelectric conversion elements 30a-30e are series-connected; the photoelectric conversion element 30a, which is located at one terminus of the plurality of series-connected photoelectric conversion elements 30a-30e, is connected to a first terminal 16, and the photoelectric conversion element 30e, which is located at the other terminus, is connected to a second terminal 17. The number of the series-connected photoelectric conversion elements 30a-30e is not particularly limited as long as it is plural.

The base 2 is a base for forming the photoelectric conversion layers. When the solar cell module has a plurality of series-connected solar cells, the plurality of series-connected solar cells may be disposed on a single base 2.

When the base 2 is located in a light incident part, the base 2 is made of a translucent material. The base 2 may be a glass substrate or a transparent organic film. This allows light to enter the interiors of the photoelectric conversion elements 30a-30e. When the base 2 is a flexible organic film, the solar cell module 40 is a flexible solar cell module.

Specific examples of materials for the organic film to be formed into the base 2 include polyethylene terephthalate (PET), polybutylene terephthalate (PBT), polyphenylene sulfide (PPS), polyetherimide (PEI), polytetrafluoroethylene (PTFE), polyamideimide (PA), and polyethylene naphthalate (PEN), but any other resin can also be used as long as it meets the requirement. The film thickness of the organic film to be formed into the base 2 is desirably 50-100 μm.

When the base 2 is a transparent organic film, a second barrier layer 15 may be disposed on one main face of the base 2. The second barrier layer 15 is a layer of a material having a high gas barrier property. This allows prevention of the interiors of the photoelectric conversion elements 30a-30e from degradation due to moisture and oxygen in air. The second barrier layer 15 is also a layer of an insulator material. This enables suppression of flow of leakage current. The film thickness of the second barrier layer 15 can be several tens to 100 nm. This allows the second barrier layer 15 to have light permeability. Moreover, the solar cell module 40 can be flexible. Specific examples of materials for the second barrier layer 15 include silicon oxide and aluminum oxide. Any other oxidized substance or insulator can also be used as a material for the second barrier layer 15, as long as the second barrier layer 15 has gas barrier properties, insulating properties, and light permeability. Examples of main film-forming methods for the second barrier layer 15 include sputter deposition and vacuum deposition.

The first conductive layers 3a-3e are disposed on the base 2 (or on the second barrier layer 15), and are electrodes for extracting current generated by photovoltaic force of the photoelectric conversion layers of the photoelectric conversion elements 30a-30e. When the base 2 is in the light incident part, the first conductive layers 3a-3e can be transparent conductive films. The transparent conductive film is formed of a conductive transparent material such as aluminum-doped zinc oxide (AZO), indium zinc oxide (IZO), gallium-doped zinc oxide (GZO), fluorine-doped tin oxide (FTO), and indium tin oxide (ITO). The first conductive layers 3a-3e may also have a configuration where fine lines of a conductive metal, such as silver, are patterned on an oxide, such as the conductive transparent material described above.

The sheet resistance of the first conductive layers 3a-3e is preferably 10 Ω/sq or less, and the light transmittance of the first conductive layers 3a-3e is preferably 80% or more. Examples of formation methods for the first conductive layers 3a-3e include sputter deposition, vacuum deposition, conductive paste application/printing technologies, and low-temperature firing technologies.

When the plurality of photoelectric conversion elements 30a-30e is disposed on the base 2, a transparent conductive film (first conductive layers 3a-3e) formed on the base 2 is divided by the photoelectric conversion elements 30a-30e. For example, since the solar cell module 40 as shown in FIG. 14 include five photoelectric conversion elements 30a-30e, the transparent conductive film is divided to form five first conductive layers 3a-3e. A groove separating adjacent two of the first conductive layers 3a-3e may fill with the porous insulator layers 6a-6e or the like.

A first terminal 16 of the solar cell module 40 is formed on the organic film, which is the base 2, and a portion of the first terminal 16 penetrates the organic film (base 2) and the second barrier layer 15, and contacts or electrically connects to the first conductive layer 3a of the photoelectric conversion element 30a at the end of the series-connected photoelectric conversion elements 30a-30e. The first terminal 16 can be used to extract current produced by photovoltaic force of the solar cell module 40. Examples of materials for the first terminal 16 include SnZn-based solder paste. Any other conductive paste and electrode material can be used as long as meeting the requirement.

The photoelectric conversion layers are layers in which light energy is converted into electrical energy. Specifically, the photoelectric conversion layers receive light, thereby producing photovoltaic power. The photoelectric conversion layers are disposed on the first conductive layers 3a-3e, and include the porous hole-blocking layers 5a-5e (including the photoabsorption layers in pores), the porous insulator layers 6a-6e (including the photoabsorption layers in pores), the electron-blocking layers 8a-8e (including the photoabsorption layer between a coating layer and a cover layer).

The hole-blocking layer is a layer that transports an electron generated by photoexcitation in the photoabsorption layer to the first conductive layers 3a-3e. The hole-blocking layer is thus made of a material that allows an electron generated in the photoabsorption layer to easily move to the hole-blocking layer, and then the electron in the hole-blocking layer to easily move to the first conductive layers 3a-3e. The hole-blocking layer can include the dense hole-blocking layers 4a-4e and the porous hole-blocking layers 5a-5e. The dense hole-blocking layers 4a-4e can be omitted. A Pore in the porous hole-blocking layers 5a-5e includes a photoabsorption layer containing an organic-based photoelectric conversion material.

The hole-blocking layer may also be a seed layer for leading an organic-based photoelectric conversion material contained in the photoabsorption layer to oriented growth. This provides improved crystalline quality of a compound having a perovskite crystal structure forming the photoabsorption layer.

The hole-blocking layer is, e.g., a titanium oxide layer (TiO₂ layer). Titanium oxide contained in the titanium oxide layer may further have a surface where a TiN layer or TiO₂₋ₓNₓ layer is formed. The TiN layer or TiO₂₋ₓNₓ layer is to be a seed layer for leading an organic-based photoelectric conversion material to oriented growth.

For example, a TiN (NaCl structure) layer having a film thickness of 5-30 nm may be formed on the surface of a dense TiO₂ layer by forming the dense TiO₂ layer, which represents the dense hole-blocking layers 4a-4e, on a transparent conductive film served as the first conductive layer 3, and subjecting the surface of the dense TiO₂ layer to surface modification by nitrogen plasma. A TiN (NaCl structure) layer having a film thickness of 5-30 nm may also be formed on the surface of a TiO₂ particle to be build up with a porous TiO₂ layer by forming the porous TiO₂ layer, which represents the porous hole-blocking layers 5a-5e, and then subjecting the surface of the porous TiO₂ layer to surface modification by nitrogen plasma.

The lattice constants of TiO₂ (rutile structure) and TiN (NaCl structure) exhibit relatively good consistency, and a good interface with few defects is formed between a TiO₂ layer composed of TiO₂ and a TiN layer composed of TiN. Formation of a mixed crystal substance, TiO₂₋ₓNₓ, proximate to the interface causes continuous change of the lattice constants, and enables suppression of generation of an interfacial defect. In the TiN layer, upon exposure to the air after surface modification by nitrogen plasma, a reoxydised layer (TiO₂ layer) is formed with a thickness of several nm on the surface, but the generated TiO₂ layer is too thin to induce structure relaxation of the lattice constant, thus maintaining the lattice constant of the underlying TiN layer. Formation of a perovskite compound crystal on such a stacked structure of titanium oxide, titanium nitride, and titanium oxide causes generation of a built-in potential so as to improve extraction efficiency of electrons and barrier efficiency of holes, and allows implementing a high efficiency solar cell.

After the transparent conductive film (first conductive layer) and the hole-blocking layer are formed on the organic film (base 2) covered with the second barrier layer 15, incisions are made in the transparent conductive film and the hole-blocking layer by laser scribing in order to separately form the photoelectric conversion elements 30a-30e on the organic film (base 2). A laser wavelength used is desirably in the infrared range. For example, incisions are made in the transparent conductive film to form the first conductive layers 3a-3e, as shown in FIG. 14. The second barrier layer 15 has no incision.

Next, the porous insulator layers 6a-6e are formed on the hole-blocking layer of an intermediate product after incision by laser scribing. The porous insulator layers 6a-6e are built up with inorganic microparticles (first insulator particles) (particle diameter: 50-200 nm) of an insulator material. The porous insulator layers 6a-6e can have a porous structure built up with the first insulator particles and a binder resin. A material for the first insulator particles 13, which build up the porous insulator layers 6a-6e, are desirably a material having a wide band gap such as zirconium oxide, alumina, and silicon oxide. As described later, the photoabsorption layers are disposed in pores of the porous insulator layers 6a-6e. Accordingly, composite layers are formed including the porous insulator layers 6a-6e and the photoabsorption layers. Note that the photoabsorption layers are disposed in pores of the porous insulator layers 6a-6e, and thus omitted in the cross-sectional view in FIG. 14.

The porous insulator layer can be formed by screen printing. After formation of the porous insulator layer, an incision is made in a portion of the porous insulator layer by laser scribing in order to connect the first conductive layers 3a-3e of one photoelectric conversion element 30 of two adjacent photoelectric conversion elements 30 (30a-30e) to the electron-blocking layers 8a-8e and the second conductive layers 11a-11e of the other photoelectric conversion element 30. A laser wavelength used is desirably in the visible range. For example, incisions are made in the porous insulator layer to form the porous insulator layers 6a-6e, as shown in FIG. 14. This laser scribing removes a portion of the porous insulator layer, but do not remove the first conductive layers 3a-3e and second barrier layers 15a-15e.

Next, coating layers that serve as portions of the electron-blocking layers 8a-8e are formed on the porous insulator layers 6a-6e. The electron-blocking layers 8a-8e are layers that catch holes generated in the photoabsorption layers and transport to the second conductive layers 11a-11e, which are anodes, thereby blocking transfer of electrons generated in the photoabsorption layers to the electron-blocking layers 8a-8e. The electron-blocking layers 8a-8e includes the coating layers formed on the porous insulator layers 6a-6e, and cover layers.

Specific examples of materials for the electron-blocking layer 8 (the coating layer and the cover layer) include inorganic compounds such as Cu₂O, NiO, and ZnS. Use of such a material enables efficient blocking of electrons photoexcited in an organic-based photoelectric conversion material in the photoabsorption layers to transfer to the electron-blocking layers 8a-8e, and allows implementing a high-efficiency solar cell.

The coating layers can be formed on the porous insulator layers 6a-6e with e.g., sputter deposition. When the coating layer has a film thickness of 25 nm or more to 80 nm or less, a permeation pore(s) can be formed in the coating layer. This enables an organic-based photoelectric conversion material solution (perovskite compound solution) used for formation of the photoabsorption layers to pass through the coating layers, and allows the organic-based photoelectric conversion material solution to permeate the porous insulator layers 6a-6e and the porous hole-blocking layers 5a-5e.

Next, the photoabsorption layer is formed. A perovskite compound having the perovskite-type crystal structure contained in the photoabsorption layer can be synthesized by using a compound indicated by AX and a compound indicated by BX, as raw materials. In particular, the perovskite compound can be synthesized by mixing an AX solution and a BX₂ solution and stirring with heating, thereby providing a perovskite compound solution in which the perovskite compound is dissolved.

When the perovskite compound solution is applied on the coating layers, the perovskite compound solution passes through the permeation pores in the coating layers to permeate the porous insulator layers 6a-6e, and further permeates the porous hole-blocking layers 5a-5e. At this stage, pores of the porous insulator layers 6a-6e and pores of the porous hole-blocking layers 5a-5e are filled with the perovskite compound solution. On the coating layers, applied films of the perovskite compound solution are also formed so as to expose portions of the coating layers. Subsequently, the intermediate product is heated to dry up the perovskite compound solution, thereby enabling deposition and crystallization of the perovskite compound in the pores of the porous insulator layers 6a-6e, in the pores of the porous hole-blocking layers 5a-5e, and on the coating layers, and allowing formation of the photoabsorption layers.

After formation of the photoabsorption layers, the cover layers (electron-blocking layers 8a-8e) is formed on the photoabsorption layers. This allows formation of the electron-blocking layers 8a-8e so as to interpose the photoabsorption layer between the coating layer and the cover layer, thereby providing a wider contact area between the photoabsorption layer and the electron-blocking layer, and allowing efficient extraction of holes generated in the photoabsorption layers, from the second conductive layers 11a-11e. The cover layers can be formed by, e.g., sputter deposition.

Next, the second conductive layers 11a-11e are formed on the electron-blocking layers 8a-8e (cover layers). The second conductive layers 11a-11e are electrodes for extracting current generated by photovoltaic force of the photoelectric conversion layers of the photoelectric conversion elements 30a-30e. The second conductive layers 11a-11e are, e.g., metal films having a work function of 5 eV or more. Inclusion of a metal having a high work function (5 eV or more) in the second conductive layers 11a-11e causes generation of a bend of a band structure that makes a hole flow smoother, between the photoabsorption layers and the second conductive layers 11a-11e. Examples of materials for the second conductive layers 11a-11e include metals such as Ni, Pt, and Pd. The film thickness of the second conductive layers 11a-11e are desirably 50 nm-150 nm. The second conductive layers can be formed by sputter deposition, vacuum deposition, or the like.

After formation of the second conductive layers, incisions are made in portions of the electron-blocking layers 8a-8e and second conductive layers 11a-11e by laser scribing in order to form them into a series-connected circuit of the photoelectric conversion elements 30a-30e adjacent to one another on the base 2. The incisions are made in the dense hole-blocking layers 4a-4e, the porous hole-blocking layers 5a-5e, the porous insulator layers 6a-6e, the electron-blocking layers 8a-8e, and the second conductive layer, in order to make the first barrier layer 14, which is described later, function as a varistor 21. A laser wavelength used is desirably in the ultraviolet range. For example, incisions are made in an electron-blocking layer and a second conductive layer to form the electron-blocking layers 8a-8e and the second conductive layers 11a-11e, as shown in FIG. 14. Additional incisions can be formed to form the varistor 21 as shown in FIG. 14.

The first barrier layer 14 is a dense inorganic material layer, and can be disposed so as to cover a side part of the photoelectric conversion layer. The first barrier layer 14 can also be disposed so as to cover the whole rim of the photoelectric conversion layer. The first barrier layer 14 can also be disposed so as to cover the upper faces of the second conductive layers 11a-11e. Such first barrier layer 14 enables suppression of entry of moisture (water vapor or the like) into the photoabsorption layers, and allows suppression of degradation of the photoelectric conversion elements 30a-30e. Furthermore, the first barrier layer 14 is a dense inorganic material layer, and thus provides suppression of reduction in a barrier function of the first barrier layer 14 due to ultraviolet radiation, temperature change, and the like. Moreover, full coating of the photoelectric conversion layers with the first barrier layer 14, the first conductive layers 3a-3e, the base 2, the second barrier layer 15, and the like provides improved barrier properties against water vapor.

The first barrier layer 14 may also be made of a material exhibiting varistor characteristics. The first barrier layer 14 can also be disposed to connect the first conductive layers 3a-3e and the second conductive layers 11a-11e such that the first barrier layer 14 and the photoelectric conversion layers are parallel-connected. Varistor characteristics refers to voltage-current characteristics to immediately begin to flow current at a certain voltage (current nonlinearity). A material exhibiting varistor characteristics is not particularly limited as long as it is a material that can be used for a varistor element.

The thickness of the first barrier layer 14 can be, e.g., 30 nm or more to 100 nm or less.

The first barrier layer 14 is formed on the second conductive layers 11a-11e after laser scribing. The first barrier layer 14 can also be formed so as to fill incisions. This enables covering the rim and upper face of the photoelectric conversion layer with the first barrier layer 14. The first barrier layer 14 can also be connected to the first conductive layers 3a-3e and the second conductive layers 11a-11e such that the first barrier layer 14 and the photoelectric conversion layers are parallel-connected.

A portion of the first barrier layer 14 is parallel-connected as a varistor element structure to the photoelectric conversion layers, thereby providing the photoelectric conversion elements 30a-30e integrally with a bypass diode (a varistor in the first barrier layer 14). This allows suppression of reduction in electrical generation efficiency due to a shadow on a module, with low cost.

The first barrier layer 14 can contain, e.g., zinc oxide (ZnO) as a main material, and silicon oxide, aluminum oxide, titanium oxide, or the like as an additive material. The varistor characteristics (I=KVα, K: element-specific constant, α: voltage nonlinear coefficient) of the first barrier layer 14 between the first conductive layers 3a-3e and the second conductive layers 11a-11e has desirably α=20-60 and a bend point voltage of 2 V or more.

The back face substrate 19 is a substrate placed over the first barrier layer 14, and the photoelectric conversion layers are located between the base 2 and the back face substrate 19. The back face substrate 19 may be a substrate of a series-connected solar cell, or a substrate of a solar cell module. The back face substrate 19 may be a glass substrate, a transparent organic film, or an opaque organic film.

When the back face substrate 19 is an organic film, a third barrier layer 18 may be disposed on one of the main faces of the back face substrate 19. The third barrier layer 18 is a layer of a material with high gas barrier properties. This allows prevention of the interiors of the photoelectric conversion elements 30a-30e from degradation due to moisture and oxygen in air. The third barrier layer 18 is also a layer made of an insulator material. This enables suppression of flow of leakage current. The film thickness of the third barrier layer 18 can be several tens to 100 nm. Specific examples of materials for the third barrier layer 18 include silicon oxide and aluminum oxide.

The second terminal 17 of the solar cell module is formed on the organic film, which is the back face substrate 19, and a portion of the second terminal 17 penetrates the organic film (back face substrate 19) and the third barrier layer 18, and contacts or connects via the first barrier layer 14 to the second conductive layer lie of the photoelectric conversion element 30e at the end of the series-connected photoelectric conversion elements 30a-30e. The first terminal 16 and the second terminal 17 can be used to extract current produced by photovoltaic force of the solar cell module 40. Examples of materials of the second terminal 17 include SnZn-based solder paste. Any other conductive paste and electrode material can be used as long as meeting the requirement.

After formation of the first barrier layer 14 on the second conductive layers 11a-11e or the like, an organic film (back face substrate 19) including the second terminal 17 formed therein is attached to the first barrier layer 14 via a laminate sheet 25, and subjected to heat lamination, thereby completing the solar cell module 40, in which the plurality of photoelectric conversion elements 30a-30e are series connected. Note that perforation is made at a position of the second terminal 17 in the laminate sheet 25, which is interposed between the first barrier layer 14 and the back face substrate 19. Thus the second terminal 17 and the first barrier layer 14 are well connected at lamination. This causes formation of a varistor between the second conductive layer lie and the second terminal 17. At power generation, high voltage is applied between the second conductive layer lie and the second terminal 17, thus providing no obstacle for extraction of current because of the varistor characteristics. The second conductive layer lie and the second terminal 17 may also contact each other. The laminate sheet 25 may be made of a common laminate material, and is desirably a resin film with a laminate temperature of 180 degrees centigrade or less and high waterproofness.

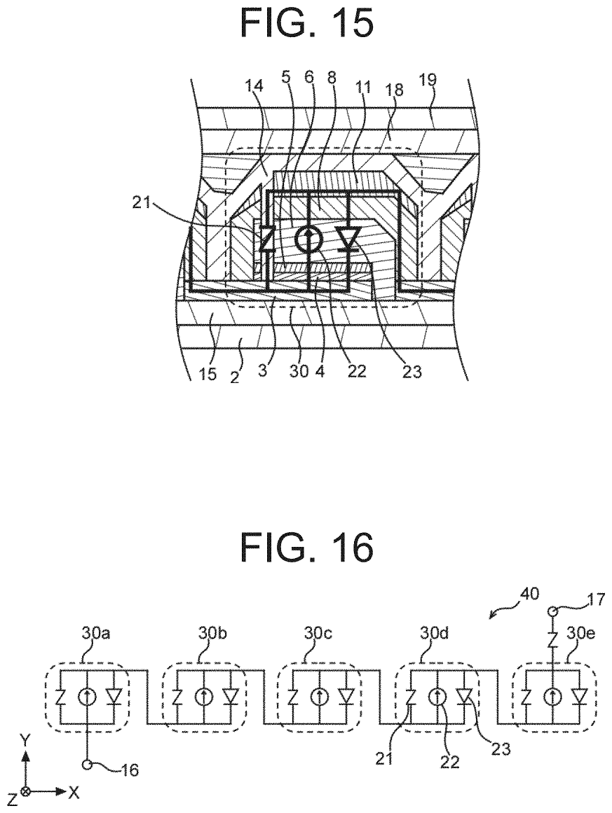

FIG. 15 overlays a schematic cross-sectional view of one photoelectric conversion element 30 included in the solar cell module 40, and an equivalent circuit of the photoelectric conversion element 30. FIG. 16 depicts an equivalent circuit of the solar cell module 40.

As shown in FIG. 15, the photoelectric conversion layer can be indicated as a current source 22 and a diode 23. In addition, the first barrier layer 14 in an incision is indicated as the varistor 21, and the varistor 21 is connected to the first conductive layer 3 and the second conductive layer 11 so as to be parallel-connected to the photoelectric conversion layers.

Note that the description for the photoelectric conversion elements in the first and second embodiments also applies to the photoelectric conversion element included in the solar cell module in the third embodiment unless there is a contradiction.

### INDUSTRIAL APPLICABILITY

The photoelectric conversion element and solar cell module according to the embodiments of the present disclosure can be used for a solar light power generation system such as a mega solar system, a solar cell, a power supply for a small-sized portable device, and the like.

What is claimed is:

1. A photoelectric conversion element comprising: a first conductive layer; a porous hole-blocking layer disposed on the first conductive layer; a porous insulator layer disposed on the porous hole-blocking layer; photoabsorption layers disposed in a pore of the porous hole-blocking layer and in a pore of the porous insulator layer and comprising an organic-based photoelectric conversion material; an electron-blocking layer disposed on the porous insulator layer; and a second conductive layer disposed on the electron-blocking layer.

2. The photoelectric conversion element according to claim 1, wherein the organic-based photoelectric conversion material is a compound or organic complex having a perovskite-type crystal structure.

3. The photoelectric conversion element according to claim 1, wherein the electron-blocking layer comprises a first coating layer coating an upper face of the porous insulator layer, and a cover layer disposed on the first coating layer,
wherein the photoabsorption layer is further disposed between the first coating layer and the cover layer.

4. The photoelectric conversion element according to claim 1,
wherein the electron-blocking layer is disposed so as to cover a surface of an insulator particle;
wherein the electron-blocking layer and the insulator particle form a particle having a core shell structure;
wherein a plurality of the particles having the core shell structure are assembled to form a porous layer;
wherein the porous layer is placed between the porous insulator layer and a second conductive layer; and
wherein the photoabsorption layer is further disposed in a pore of the porous layer.

5. The photoelectric conversion element according claim 4, wherein the electron-blocking layer includes a second coating layer coating an upper face of the porous layer.

6. The photoelectric conversion element according to claim 1, wherein an energy level at an upper end of a valence band of a material of the porous hole-blocking layer is 0.5 eV or more lower than an energy level at an upper end of a valence band of the organic-based photoelectric conversion material.

7. The photoelectric conversion element according to claim 1, wherein an energy level at a lower end of a conduction band of a material of the electron-blocking layer is 0.5 eV or more higher than an energy level at a lower end of a conduction band of the organic-based photoelectric conversion material.

8. The photoelectric conversion element according to claim 1,
wherein a material of the porous hole-blocking layer is TiO₂,
wherein a TiO₂ particle building up the porous hole-blocking layer has a surface comprising a stacked structure of TiO₂/TiN/TiO₂.

9. The photoelectric conversion element according to claim 1, wherein a material of the electron-blocking layer is Cu₂O, NiO, or ZnS.

10. The photoelectric conversion element according to claim 1, wherein a material of the second conductive layer is a metal having a work function of 5.0 eV or more.

11. A solar cell module comprising a plurality of the photoelectric conversion elements set forth in claim 1, a base, and a barrier layer,
wherein the plurality of photoelectric conversion elements is integrated so as to be series-connected on the base,
wherein the barrier layer is disposed to be coated on the upper faces of the plurality of the photoelectric conversion elements, and
wherein a material of the barrier layer is an inorganic material with varistor characteristics.
